(19) United States
(12) Patent Application Publication
(10) Pub. No.: US 2010/0241815 A1
(43) Pub. Date: Sep. 23, 2010

(54) Hybrid Storage Device

(75) Inventor: Chuck MCMANIS, Sunnyvale, CA (US)

Correspondence Address: STERNE, KESSLER, GOLDSTEIN & FOX, P.L.L.C., 1100 NEW YORK AVENUE, N.W., WASHINGTON, DC, 20005, US

(73) Assignee: Google Inc., Mountain View, CA (US)

(21) Appl. No.: 12/408,036

(22) Filed: Mar. 20, 2009

(51) Int. Cl. G06F 12/00; G06F 17/30; G06F 15/177; G11C 5/14

(52) U.S. Cl. 711/154; 365/229; 713/2; 713/300; 711/E12.083; 711/E12.001; 711/E12.084

(57) ABSTRACT

In one embodiment, a hybrid storage device including a persistent memory, a volatile memory, a processor, a memory loader module that enables the processor to load a first set of information from the persistent memory device to the volatile memory device, to organize the first set of information according to a predetermined format, and a storage drive interface controller that enables the processor to receive information access requests from a host computer, to provide a second set of information from the volatile memory device to the host computer, and to provide a metadata descriptive of the first set of information to the host computer is disclosed. A host computer is enabled to access the first set of information using metadata provided by the storage drive interface controller without having the first set of information in a local memory of the host computer. The time required to access the first set of information is reduced by having the first set of information in volatile memory in the hybrid storage device. Other embodiments include, a system having a host computer and a hybrid storage device and methods using a hybrid storage device in a host computer.

### BACKGROUND

This invention relates generally to data storage devices.

### BACKGROUND ART

The time taken to complete the startup-process and come to an operational state after normal power-on or system reset, the extent to which a system is vulnerable to security compromises particularly by unauthorized modifications to the boot-up configurations of the system, and the ability to recover from system failures, are often key performance factors in computer systems including processing servers, storage servers, and various embedded computer systems. The boot-up process and file access are aspects that affect these performance factors.

When a computer is powered on, generally, a BIOS (Basic Input Output System) program that is resident in a read-only memory (ROM) begins executing. The BIOS performs its many startup activities, including hardware detection and verification tests, and attempts to invoke a program resident in a known area, such as, for example, in the master boot record (MBR) of the boot device, and pass control to that program. The boot device is a local or network attached storage device that is configured to be bootable and noted as such by the computer. The program resident in the MBR, for example, can be a boot loader program that permits the loading of different operating systems. Some computer operating systems, such as, for example, the Linux operating system and many other variants of the UNIX operating system, can have a boot-up process in which, upon power-on, a relatively small operating system kernel (initial kernel) starts up, and then a root filesystem is installed before the computer becomes completely operational. The initial kernel image is typically loaded into memory from a predefined storage location by a boot loader such as, for example, the GRUB or LILO boot loaders used commonly in Linux systems. The initial kernel image can then load a root filesystem from one of many locations, including, a local disk, a removable storage device attached to the computer, or a network location. It is often the case that the root filesystem resides on the boot device.

The root filesystem includes most software modules required for the useful operation of the computer, including device drivers for various hardware components, user access information, and software and configuration to mount and access files. Although the root filesystem necessary for each type of computer may differ, in general, this multi-step boot-up process is one of the slower aspects in the operation of many computers and is often sought to be optimized. The term “computer” herein includes any computing device that comprises at least one processor and that has the capability to access files on a storage device.

The root filesystem may be substantially large, and loading a substantial part of a root file system can be time consuming. For this and other reasons, loading the root filesystem from a local disk or attached removable storage device is generally preferred to loading the root filesystem over a network.

However, for many computers, a complete root filesystem is not necessary to function. For example, many embedded devices do not need the functionality of a complete root filesystem because those devices are generally dedicated to a limited set of processing functions. Mobile telephones, set top boxes (e.g., cable boxes), gaming consoles, routers, etc., are some examples of embedded devices that may not require the functionality of a complete filesystem. In many cases, computers other than embedded devices, such as, personal computers and storage servers, may also not require complete root filesystems.

Many computers, particularly those requiring fast boot-up and fast access to data, use a solid state memory device, such as a flash disk, on which a compressed image of the root filesystem, sometimes including an operating system image, is stored. However, although solid state drives offer substantially higher reliability than their magnetic disk counterparts and other persistent memory devices, the read and write speeds are often found to slow the operating speed of these embedded systems.

Many computers, particularly those using Linux or another UNIX variant, can load the entire filesystem from a persistent storage medium, such as a magnetic disk or a solid state disk, to the computer's local random access memory (local RAM) and into a virtual disk in RAM, i.e., a RAM disk. Once the filesystem is in a RAM disk, the operating system can access it as it accesses any local disk. Creating a RAM disk and having the computer access the RAM disk in the same or similar manner in which it accesses any disk drive can improve the operating speed of the computer. The RAM disk enables fast access to files because the files are accessed in volatile memory and the need for relatively slow disk accesses to retrieve files is significantly reduced. But, because the entire filesystem is brought into the local RAM, valuable RAM capacity is denied to applications and other processes that require that RAM space.

There is a long felt need to provide storage capacity and access to stored information with increased speed, efficiency and reliability. In particular, systems and methods to provide access to storage that may enables startup of computer systems with increased speed, reliability and serviceability are needed.

### SUMMARY

In one embodiment, a hybrid storage device includes a persistent memory, a volatile memory, a processor, a memory loader module that enables the processor to load a first set of information, for example, a filesystem, from the persistent memory device and to organize the first set of information according to a predetermined format in the volatile memory device, and a storage drive interface controller. The storage drive interface controller enables the processor to receive information access requests from a host computer coupled to the hybrid storage device, to respond to the information access requests using the first set of information in the volatile memory device, and to provide the host computer with metadata descriptive of the first set of information. In this embodiment, the host computer is enabled to begin accessing the first set of information using the metadata without having the first set of information in a local memory of the host computer, and the time required to access the first set of information is reduced by having the first set of information in volatile memory.

In another embodiment, a system includes a host computer and a hybrid storage device coupled to the host computer. The hybrid storage device includes a persistent memory, a volatile memory, a processor, a memory loader module that enables the processor to load a first set of information from the persistent memory device to the volatile memory device and to organize the first set of information according to a predetermined format in the volatile memory device, and a storage drive interface controller. The storage drive interface controller enables the processor to receive information access requests from a host computer and to respond to the information access requests using the first set of information in the volatile memory.

In yet another embodiment, a method includes the stages of coupling a hybrid storage device to a host computer, loading a first set of information from a persistent memory device to a volatile memory device located in the hybrid storage device and organizing the first set of information according to a predetermined format in the volatile memory device, loading access information from the volatile memory device to a local random access memory (local RAM) located in the host computer, and accessing a second set of information using the access information located in the local RAM, where the first set of information includes the second set of information.

Further features and advantages of the present invention, as well as the structure and operation of various embodiments thereof, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

Reference will be made to the embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments.

FIG. 1 shows a system that includes a host computer and a hybrid storage device, according to an embodiment of the present invention.

FIG. 2 shows components of the hybrid storage device according to an embodiment of the present invention.

FIG. 3 shows a high level flowchart of a method of using a hybrid storage device, according to an embodiment of the present invention.

FIG. 4 is a more detailed flowchart of the events that occur when the hybrid storage device is powered on shown in FIG. 3, according to one embodiment of the present invention.

FIG. 5 is a more detailed flowchart of the “access filesystem” stage shown in FIG. 3, according to one embodiment of the present invention.

FIG. 6 is a detailed flowchart showing the processing flow when a data block is brought from the hybrid storage device to the local memory of the host computer, according to an embodiment of the present invention.

### DETAILED DESCRIPTION OF EMBODIMENTS

While the present invention is described herein with reference to illustrative embodiments for particular applications, it should be understood that the invention is not limited thereto. Those skilled in the art with access to the teachings herein will recognize additional modifications, applications, and embodiments within the scope thereof and additional fields in which the invention would be of significant utility.

The present invention, in an embodiment, enables a host computer to benefit from the ability to access a filesystem in volatile memory while not being disadvantaged by having a substantial amount of its local memory (e.g. random access memory, or RAM, locally attached to the CPU is generally the most expensive memory in the system) dedicated to the filesystem. In one embodiment of the present invention, a hybrid storage device (HSD) having a persistent memory device such as a solid state memory device (e.g., flash memory) is described. The HSD includes its own processor and a volatile memory to which a filesystem resident in the persistent memory device can be loaded. A disk interface and a disk controller in the HSD allows processes in an external device, such as, for example, a host computer, that is coupled to the HSD, to access files in the volatile memory of the HSD. In some embodiments of the present invention, the HSD may be a removable device coupled to the host computer, and in other embodiments the HSD may be a device integrated into the host computer.

An example application and use of an embodiment of the present invention is the use of a HSD to allow a server to boot-up using a root filesystem that is stored on a flash memory device on an attached HSD. For example, a compressed Linux® root filesystem may be stored on a persistent memory device in the HSD. When the HSD is coupled to the server, the Linux root filesystem is uncompressed into a volatile memory under the direction of the local processor of the HSD. To the host computer, the filesystem in volatile memory of the HSD appears as a filesystem in a persistent storage device. For example, in an HSD configured as a boot device, the filesystem in the volatile memory of the HSD can include an area corresponding to the first sector of a bootable disk that contains an MBR. Metadata, including inode information, of the filesystem may be exported by the HSD to the local memory of the host computer. The host computer can then access the entire filesystem in volatile memory of the HSD using some form of a disk interface. The host computer would access the volatile memory of the HSD in a manner that is same or similar to how it accesses a directly attached disk drive.

By enabling processes in a host computer to access a root filesystem without the latency involved in loading up the filesystem from a flash device to volatile memory and without occupying large amounts of local RAM to maintain a RAM disk hosting the filesystem, an efficient storage device is provided with reliable storage that can reduce failures and reduce the time required to recover after failures. Also, because, as in the case of using an embodiment of the present invention to access the root filesystem, any changes to the files would occur in the HSD's volatile memory, the exposure of the server to security threats, such as trojan programs, viruses, and unauthorized modifications to compromised boot-up configuration files, is reduced. For example, even if malicious code succeeds in altering a user privileges file, unless a specific command is given to write the contents of the volatile memory to a persistent memory or it has been configured to so, the system is subject to the changes in the altered user privileges file only until the next power cycle, because the changes are only made to the file in volatile memory.

Because, in many embodiments of the present invention, the HSD interfaces to the host computer using a standard disk interface, for example, Serial Advanced Technology Attachment (SATA), little or no software modification is required in the host computer to enable processes in the host computer to view the volatile memory in the HSD as a disk. The persistent memory device in the HSD remains transparent to most processes in the host computer. By presenting the volatile memory in the HSD as a standard disk to the host computer, the HSD may also be used for such tasks as, general file storage, for paging and for virtual memory.

As used in this disclosure, the term “host computer” applies to any processing device to which a HSD can be coupled. In the remainder of this disclosure, the composition of the present invention in some of its embodiments is described, followed by a description of the processing stages involved.

### System Components

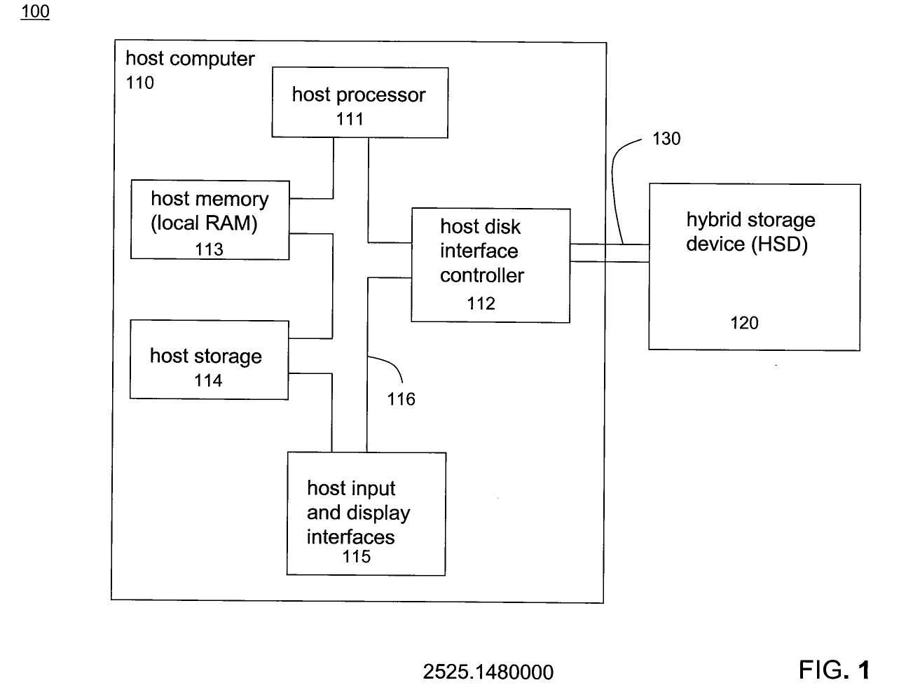

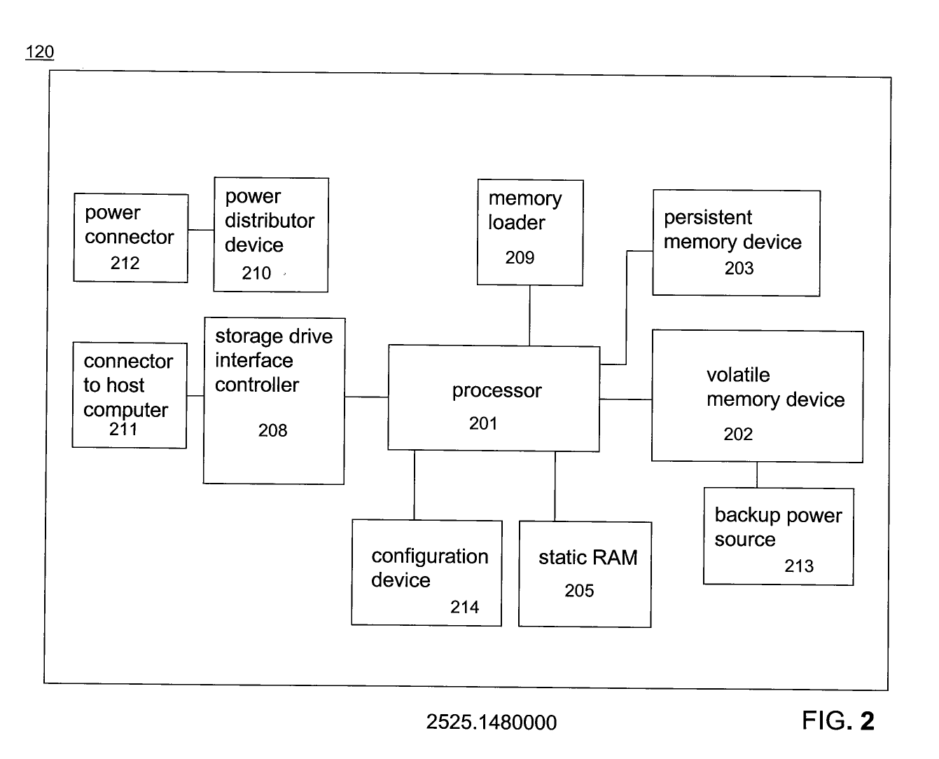

FIG. 1 shows a common usage scenario 100 of an embodiment of the present invention. A HSD 120 is coupled to a host computer 110. HSD 120 is described below with respect to FIG. 2. Host computer 110 can be any processing device, such as, including but not limited to, a commercially available computer (e.g., personal computer), personal digital assistant, mobile phone or other mobile electronic device having a processor, digital video recorder, network router, game console, set-top box, kiosk or other embedded processing platform. Host computer 110 includes several components, including a host processor 111, host memory (local RAM) 113, host storage 114, host input and display interfaces 115, host disk interface controller 112, and a host communications bus 116 that interconnects the components 111, 112, 113, 114, and 115. Host processor 111 can be any commercially available processor or special purpose processor. Host memory 113 includes random access memory (RAM). In the rest of this document, host memory 113 may be referred to as local RAM to distinguish it from other volatile memory devices, particularly RAM present in HSD 120. Host storage 114 may include a form of non-volatile storage such as a magnetic disk or flash disk. Host input and display interfaces 115 may include one or more of, keyboard, mouse, display device, and any other input/output device. Host disk interface controller 112 may be any interface controller capable of interfacing with HSD 120. For example, host disk interface controller 112 may be an interface controller corresponding to a disk interface standard such as, Serial Advanced Technology Attachment (SATA) or one of its variants, Small Computer System Interface (SCSI), Integrated Drive Electronics (IDE), Internet Small Computer Interface (iSCSI), Fiber Channel, or another standard or special purpose disk drive interface protocol. Host communications bus 116 can include one or more standard or special purpose device interconnects such as, Peripheral Component Interconnect (PCI) or a variant, Industry Standards Architecture (ISA), Extended Industry Standards Architecture (EISA). Host computer 110 connects to HSD 120 using an interface connector 130. Although shown in FIG. 1 as a directly attached peripheral device to host computer 110, in other embodiments HSD 120 can be integrated into host computer 120 or can be coupled through a network to host computer 120.

FIG. 2 shows components of HSD 120 in one embodiment of the present invention. In this embodiment, HSD 120 includes a processor 201 is coupled to a persistent memory device (e.g., solid state memory device) 203, a volatile memory device 202, a static RAM memory device 205, a storage drive interface controller 208, and a configuration device 214. In addition, processor 201 is also be coupled to a memory loader module 209. Processor 201 may include any commercially available processor, a special purpose processor, or a field programmable gate array (FPGA) such as a Altera Cyclone® II or a Xilinx Spartan® chip. Persistent memory device 203 may include a solid state memory device such as, but not limited to, a second generation Secure Digital flash card or a CompactFlash® card and a corresponding drive. Volatile memory device 202 may include a dynamic RAM (DRAM) such as double data rate two dynamic random access memory (DDR2 DRAM). Volatile memory device 202 (also referred to simply as “volatile memory”) may have its own backup power source device 213, that can provide power for a limited duration when HSD 120 is not receiving power from the host computer 110. A backup power source device 213 may include a rechargeable battery that can help increase the reliability of the HSD 120 by providing power to maintain the data in volatile memory 202 during periods of power loss to the HSD 120. Storage drive interface controller 208 may be any disk interface that corresponds to one of the disk interface types supported by the external device (for example, host computer 110) to which HSD 120 is to be coupled to, including standard disk interfaces such as SATA, SCSI, and IDE.

One or both of the modules 208 and 209 may be implemented in software, firmware, hardware or using a combination thereof. For example, computer programs that achieve all or part of the functionality of module 208 and 209 may be written in any computer programming language including C, C++, Java, Assembly, or as a hardware-specific logic definition with a language such as Hardware Definition Language (HDL). The program logic of modules 208 and 209 may then be executed by processor 201. Memory loader module 209 includes program logic that enables processor 201 to load a filesystem from persistent memory device 203 into volatile memory 202 and make that filesystem in volatile memory 202 accessible to other devices coupled to processor 201.

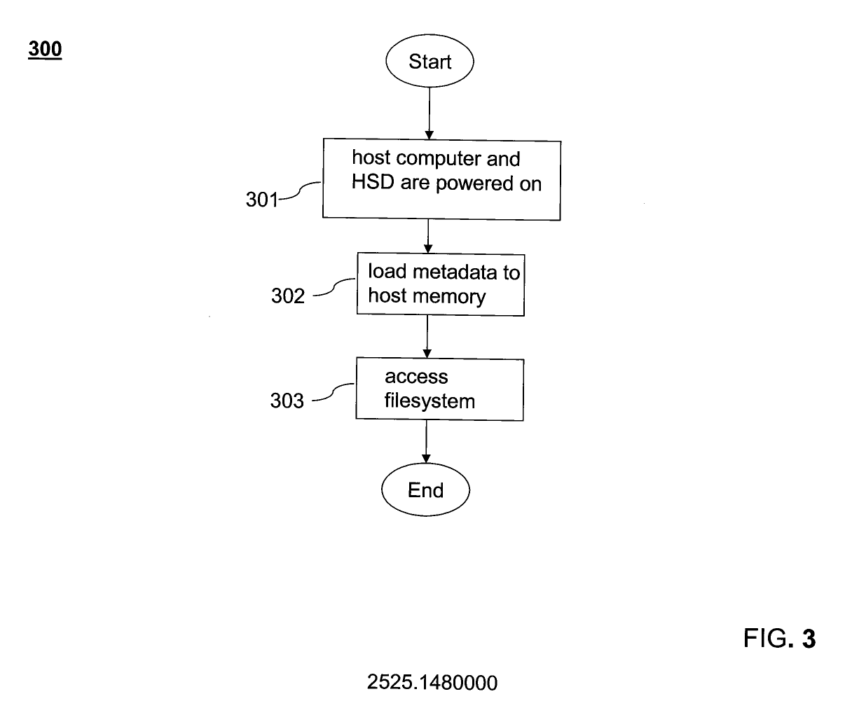

Storage drive interface controller module 208 includes program logic to enable processor 201 to permit access to the filesystem in volatile memory 202 by storage drive interface 206. Storage drive interface controller module 208, in combination with storage drive interface device 206, allows an external device, such as, for example, host computer 110, that is coupled to HSD 120 through connector 211, to access the filesystem stored in volatile memory 202 in a similar manner to accessing a filesystem local to host computer 110. For example, if storage drive interface controller 208 is compliant to the SATA disk interface standard, then it can include program logic to implement a corresponding SATA processing state machine using processor 201. Detailed explanation of how this functionality is achieved is provided below with respect to FIGS. 3-5.

In some embodiments, configuration device 214 can be used to configure and initialize various aspects of HSD 120. For example, configuration device 214 may include the functionality to initialize and format persistent memory device 203.

Configuration device 214 may include an interface that connects to an external input/output device to enable the receipt of configuration commands given manually and/or programmatically. Configuration device 214 may include a connection to processor 201 that is compliant with the JTAG (i.e., the IEEE 1149.1 standard entitled Standard Test Access Port and Boundary-Scan Architecture) standard permitting standard configuration and analysis devices to be coupled to HSD 120.

A power distributor device 210 may provide power to HSD 120. In some embodiments, power distributor device 210 may include a battery charge. In some embodiments power distributor device 210 may obtain power from an external device, such as host computer 110, through a power connector 212. For example, the SATA disk interface standard specifies a communications interface as well as a power interface.

When HSD 120 is coupled to host computer 110, a compressed filesystem in persistent memory device 203 may be loaded to and decompressed in volatile memory 202. In some embodiments, HSD 120 may have loaded a filesystem into a RAM disk in volatile memory 202 before it is coupled to host computer 110. Thereafter, processes executing in host computer 110 may access the filesystem in volatile memory 202 in a manner similar to accessing a filesystem that is local to host computer 110. The access is facilitated by disk interface controller 208 and a corresponding disk interface (for example, disk interface controller 112) on host computer 110. Description of the processing stages in achieving this and other functionalities are described below.

### Other Example Embodiments

In one embodiment, the host computer, after power on and basic initialization, will proceed to indentify locally connected storage. Typically, to identify locally connected devices, the host computer issues probe commands on its interfaces. For example, after power on and basic initialization host computer 110 initializes host disk controller 112 and proceeds to issue probe commands on interfaces including interface 130. Based on the responses received to the probe commands, host computer 110 may identify storage devices, such as, for example, HSD 120. Subsequently, the host computer identifies a boot device and a kernel is read and started. After the kernel is started, the host computer can mount any connected storage, including, such as, HSD 120. After RS 120 is mounted, host computer 110 can access any filesystem that resides on HSD 120 by issuing storage commands.

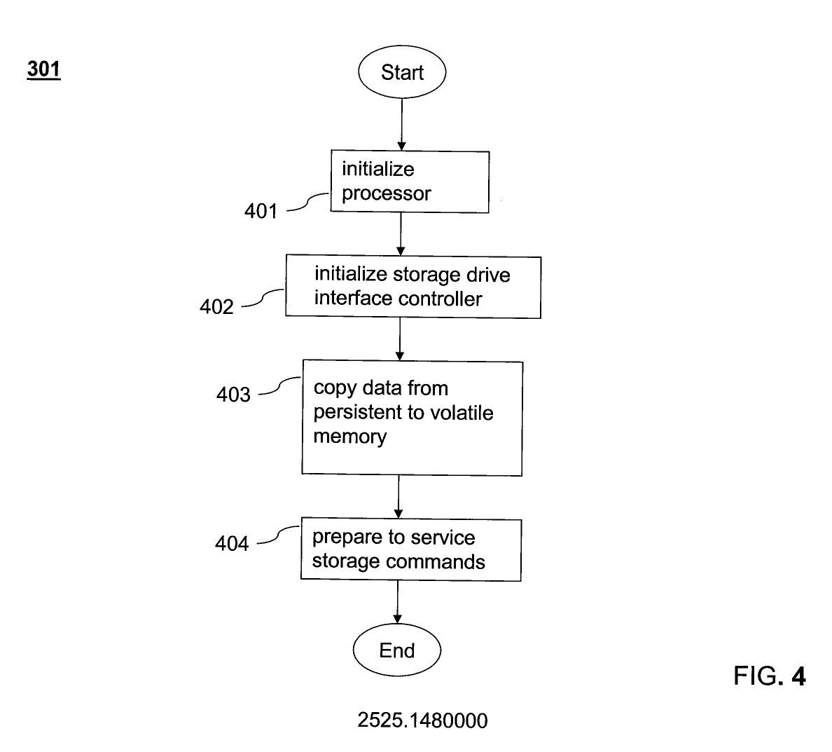

FIG. 3 illustrates a routine 300 that enables an external device, such as, for example, host computer 110, to access a filesystem that is maintained in volatile memory in a HSD, for example, HSD 120 (stages 301-303). In stage 301, the startup of the HSD is commenced. For example, the startup of the HSD may be commenced when the HSD is connected to a host computer that is already powered on, or when power is turned on to a host computer that is already connected to a HSD. A dissection of stage 301 can be found below with respect to FIG. 4. A first set of information (such as a filesystem) that was previously stored in a persistent storage device, such as, for example, persistent memory device 203 is loaded into volatile memory of the HSD, such as, for example, volatile memory 202. The first set of information may be a complete filesystem, such as, for example, a root filesystem compliant to a filesystem format such as, but not limited to, the Second Extended Filesystem (EXT2). The filesystem format defines how the data is organized in the storage media. The loading may cause the data of the filesystem to be brought into volatile memory and to be uncompressed. In stage 302, a RAM disk may be created in the volatile memory, and the RAM disk may be populated with the filesystem imported from the persistent memory device. The volatile memory can be large enough to hold the entire uncompressed filesystem in a RAM disk. In one embodiment, the RAM disk in the volatile memory of the HSD can contain a root filesystem organized according to a filesystem format such as EXT2, and data structures indicating that the storage volume represented by that RAM disk is a bootable storage device. For example, the host computer may expect the first sector of a bootable storage devices to have a particular data flag to indicate that the device is bootable.

In stage 302, a second set of information, typically a relatively small amount of data from the first set of information, may be exported from the volatile memory on the HSD to the dynamic memory on the host computer, such as local RAM 113 on host computer 110. For example, a part of an inode table of a filesystem, i.e., metadata that describes the filesystem, can be exported to the host computer. The inode table of a filesystem includes basic information necessary to identify and access files in the filesystem. The transfer of the metadata may be initiated by the HSD or by the host computer. The transfer of only the metadata to the local RAM of the host computer is generally much faster than transferring files of the filesystem due to the reduction in the volume of data to be transferred.

Having received the metadata, the host computer may now access the filesystem in stage 303. For example, in Linux systems, once the initial kernel image receives the inode table describing the root filesystem in the RAM disk, the kernel can then proceed to mount the root filesystem. After the root filesystem is mounted, processes executing on the host computer can begin accessing various files in the root filesystem. Access to the root filesystem may be made by the host computer issuing read and write commands to the HSD. The read and write commands are processed by, for example, storage interface controller 208 according to the chosen interface protocol.

In an embodiment using the Linux operating system, after mounting the initially required parts of the root filesystem, in general, the kernel locates one or more files in the root filesystem (e.g., /sbin/init) which are then executed to initialize the services and user processes that implement much of the functionality of the host computer. An init file is located either based on a parameter provided to the kernel at boot-up time, or by the kernel searching a series of predetermined locations. The processes initiated by the init file may then access other files (e.g., /etc/rc.d in some Linux and UNIX systems) in the root filesystem to invoke other user processes.

Each time the kernel accesses a directory to find, read or write to a file, the memory blocks containing that file (or part of that file) are generally brought into local RAM. As the processing progresses and the local RAM gets filled up, a paging system may be implemented, that swaps some data blocks out of local RAM to make space for new data blocks incoming from the filesystem. In some embodiments of the present invention, the data blocks that are being paged out of local memory may be selectively, for example, if that block contains some updates, written to an area in the volatile memory in the HSD. Paging data blocks out to volatile memory instead of disk storage can improve the speed of execution of processes by reducing the frequency of accessing non-volatile storage media.

In embodiments of the present invention, the entire filesystem directory structure (or necessary parts thereof) including the actual files are, in general, already in the volatile memory of the HSD at the time of being required by the kernel in the host computer. The filesystem present in the volatile memory of the HSD appears to the kernel as a directly attached disk having the root filesystem. Therefore, the local RAM may hold only the metadata and only blocks of data corresponding to those actually accessed by the kernel or related applications. Not having to maintain the entire root filesystem or substantial portions thereof in local RAM allows the local RAM to be used for numerous other processing tasks.

FIG. 4 shows stage 301 in more detail according to some embodiments of the invention. Upon receiving power to the HSD, the processor of the HSD is initialized in stage 401. Initialization of the processor is generally begun by code resident in read only memory (ROM) known simply as the BIOS (Basic Input/Output System) and may include standard processor power-on steps such as, for example and without limitation, power-on self test, initialization of other hardware components, initializing low level system routines that the operating system (once loaded) can use to access various devices and services provided by the processor, and also the initializing onboard volatile memory and RAM of the HSD. For example, in HSD 120, static RAM device 205 can store the BIOS instructions to commence initializing the HSD.

Stages 402 and 403 may be performed in any order or in parallel. In stage 402, the processor of the HSD initializes the storage drive interface controller. For example, referring back to FIG. 2, processor 201 may execute instructions to initialize storage drive interface controller 208 that is designed to interact with a corresponding disk controller on host computer 110. The storage device interface controller may respond to probe commands and identification commands received from the host computer, to enable the host computer to recognize the HSD. The processor on the HSD may also perform detection of the type and the integrity of the persistent memory device and related sanity checks. For example, the processor may verify that a loadable filesystem with a verifiable checksum is available in the persistent memory device. In one embodiment, this initialization may include, for example and without limitation, the initialization of a SATA controller state machine.

In stage 403, the processor in the HSD may trigger a signal to copy a filesystem from the persistent memory device into the volatile memory of the HSD. Such a signal may also be originated by the host computer. The signal to load the filesystem may cause the processor to invoke and execute instructions to load the filesystem from the persistent memory device into volatile memory and decompress the filesystem in volatile memory. For example, referring back to FIG. 2, the signal to copy the filesystem may cause processor 201 to execute the program logic of memory loader module 209 to load a compressed filesystem, in its entirety or in part, to volatile memory 202 and uncompress it therein. Thereafter, the uncompressed filesystem resident in volatile memory 202 may be visible to the host computer 110 as another disk drive, to which access is coordinated through storage drive interface controller 208. In an embodiment of the present invention, the first set of information may include a root filesystem uncompressed in the volatile memory of the HSD and organized according to a filesystem format, along with data structures in the volatile memory to enable the host computer to recognize the filesystem in the volatile memory as, for example, a bootable disk storage volume. For example, the host computer may expect the first disk sector of a bootable disk volume to contain an boot device indicator if it is bootable. Based on the filesystem format and the disk interface protocol a boot device indicator may be written, for example, the area in the volatile memory that corresponds to the last word in the first sector of a disk storage medium.

In stage 404, the HSD services storage commands received from the host computer. For example, a SATA controller state machine initialized in storage device controller 208 in stage 402 may be used to receive and process read and write commands received from the host computer.

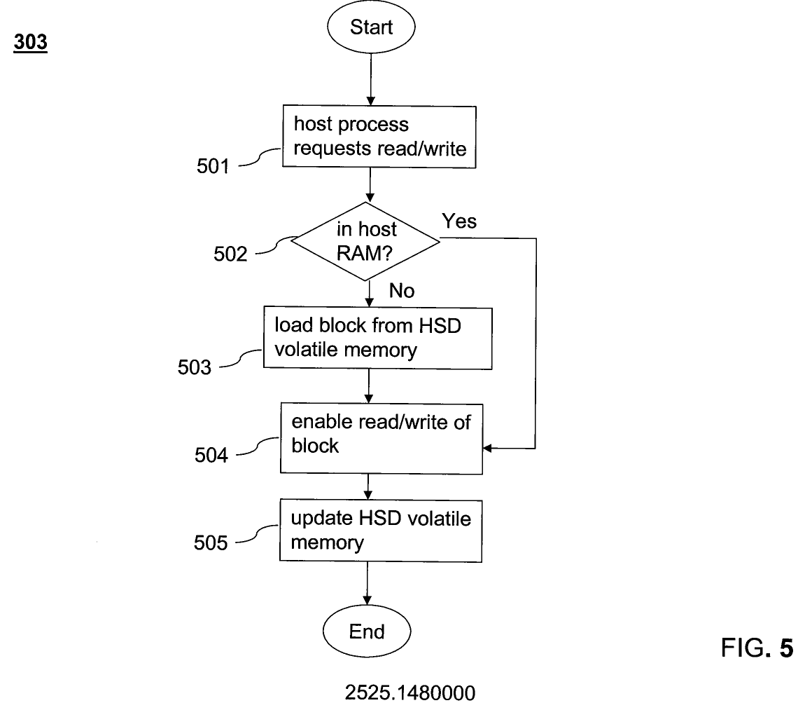

FIG. 5 is a breakdown of stage 303 according to an embodiment of the present invention. After the metadata concerning the filesystem is transferred to the local RAM of the host computer, the host computer's processes can proceed to access files and directories of the filesystem. For example, in stage 501, a process executing on the host computer's processor may request a read or write operation on a file in the filesystem. In stage 502, the inode table is checked to see if the host computer's local RAM of the HSD already contains the required file or part of the file in its memory. If the required file or part of the file is not in local RAM, the inode table would point to the presence of the data in the removable storage drive.

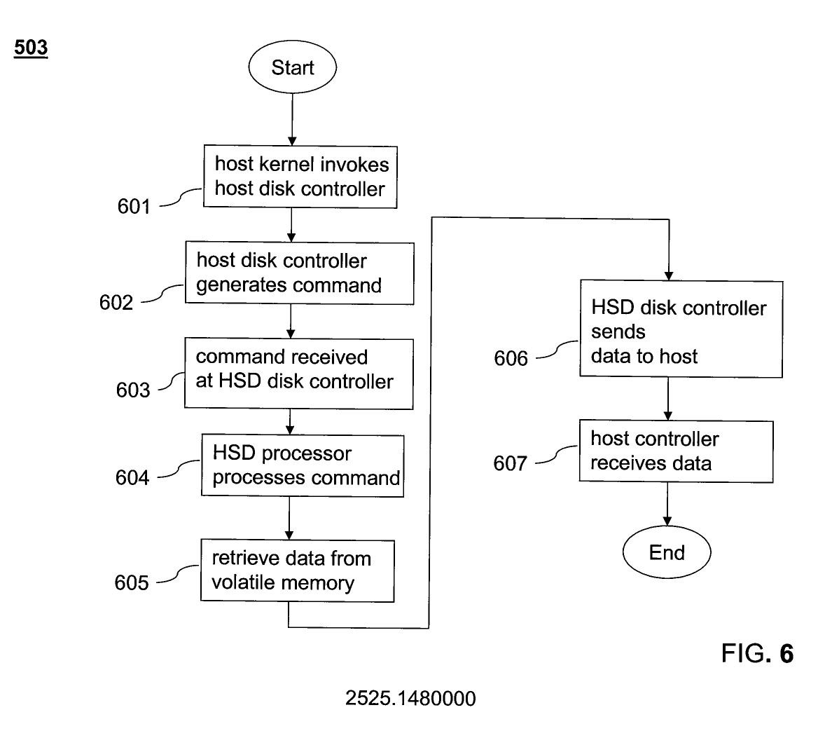

In stage 503, the processor determines that the required data is in the filesystem in the volatile memory of the HSD and initiates the process to transfer the relevant data blocks to local RAM of the host computer. Note that, in many embodiments, the filesystem and directory structure present in the volatile memory of the HSD can appear as a standard disk and directory structure to the host computer. For example, to the host computer, the HSD and its RAM disk may appear as a disk that is accessible using a SATA interface. The transfer process included in stage 503 is further described with respect to FIG. 6 below. Once the required data blocks are transferred into the local RAM of the host computer in stage 503, read/write of the blocks are enabled according to the privileges of the invoking process in stage 504. If, in stage 504, the invoking process performs write operations on the blocks of data, in some embodiments, updates will be written straight-through to the corresponding blocks in volatile memory on the HSD in stage 505. In some other embodiments, updates made in stage 504 may not be performed in a continuous straight-through manner, and instead may be performed at time intervals or upon receiving an instruction to save updates from the user.

Note that the updates made to volatile memory in the HSD, for example, in stage 505, can remain in volatile storage until, in some embodiments, the user conveys an instruction to save the updates. To save the updates, the contents of the volatile memory are written to the persistent memory device in the appropriate format. If a power loss occurs in the HSD (e.g., being momentarily decoupled from the host computer), a power-source that is attached to the volatile memory of the HSD can preserve the data and updates until the power is restored, or until the updates are written to the persistent memory device, if configured to do so. If the data in volatile memory in the HSD is not preserved by a power source on the HSD, a clean filesystem can be available on the attached HSD when the host computer is re-initiated.

FIG. 6 illustrates a breakdown, according to an embodiment of the present invention, of stage 503 that loads data from the volatile memory of the HSD into the local RAM of the host computer. Having received, for example, a write command from a user process to access some data, and having determined that the data is not currently present in the host computer local RAM, the kernel executing in the host computer processor invokes the disk controller that is responsible for interfacing with the HSD in stage 601. The host disk controller, in stage 602, generates a command according to the protocol used to interface with the HSD. In stage 603, a command to retrieve the corresponding file is received by the corresponding disk controller in the HSD. In stage 604, the processor of the HSD may process the received command to validate the command and to translate the command to a format understood by the programs and devices in the HSD. Using the translated command, the appropriate data is retrieved from volatile memory of the HSD in stage 605. The data is then provided by the processor in the HSD to the disk controller interface on the HSD, in stage 606, to be transmitted to the requesting host computer. The transmitted data is then, in stage 607, received by the disk controller in the host computer and loaded into local RAM in the host computer. The requesting process may now access the relevant data in the local RAM of the host computer.

The HSD, in another embodiment of the present invention, may be used as a location for virtual memory and/or paging memory. For example, because the volatile memory of the HSD is presented as a standard disk drive to the host computer, the host computer can map some or all of its virtual memory space to the volatile memory of the HSD. Likewise, the host computer may use the volatile memory of the HSD for swapping memory pages in and out of its local RAM. The use of the volatile memory of the HSD can result in improved performance over the conventional approaches of using a local persistent memory device as the location for virtual memory and paging memory, because disk accesses (or more generally, accesses to persistent memory devices) are reduced. The persistent memory device in the HSD generally remains transparent to the host computer in these applications.

A HSD having, in some embodiments, a compressed image of a filesystem that can be speedily uncompressed into an onboard volatile memory such that the filesystem in volatile memory can be accessed by a host computer in much the same way as it would access a disk drive is disclosed in this document. As stated above, one embodiment of the invention can be a HSD that holds a root filesystem. Having the root filesystem in relatively fast volatile memory instead of relatively slow flash memory improves access latencies. It also improves the resiliency of the system to security compromises because the changes to the filesystem remain in volatile memory until specifically directed to save to persistent memory. It improves the time to deploy and time to repair devices that use configurable root filesystems. Another aspect of embodiments of the present invention is that little or no modification of the programming code of many operating systems is required. For example, in many variants of Linux, a HSD built according to the teachings in this disclosure will be recognized as an external disk by the processor of the host computer, and may only require that the interface hosting the HSD be specified as a parameter to the kernel at start-up.

In addition, the removable storage may be used to store and access filesystems other than root filesystems. The HSD can also be used as a fast cache device or virtual memory to supplement the local memory of a host computer.

The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

What is claimed is:

1. A hybrid storage device comprising:
a persistent memory device;
a volatile memory device;
a processor, wherein the persistent memory device and the volatile memory device are coupled to the processor;
a memory loader module that enables the processor to load a first set of information from the persistent memory device and to organize the first set of information according to a predetermined format in the volatile memory device; and
a storage drive interface controller module that enables the processor to receive information access requests from a host computer coupled to the hybrid storage device, to respond to the information access requests using the first set of information in the volatile memory device, and to provide a metadata descriptive of the first set of information to the host computer,
whereby the host computer is enabled to access the first set of information using the metadata without having the first set of information in a local memory of the host computer, and whereby the time required by the host computer to access the first set of information is reduced by having the first set of information stored in the volatile memory device.

2. The hybrid storage device of claim 1, wherein the first set of information includes a filesystem, and wherein the predetermined format is a filesystem format.

3. The hybrid storage device of claim 2, wherein the filesystem is a root filesystem.

4. The hybrid storage device of claim 2, wherein the first set of information further includes a boot device indicator according to the filesystem format.

5. The hybrid storage device of claim 1, wherein information access requests include storage service commands.

6. The apparatus of claim 1, wherein the persistent memory device includes a solid state memory media.

7. The hybrid storage device of claim 1, wherein the processor includes a field programmable gate array (FPGA).

8. The hybrid storage device of claim 1, further comprising:
a static random access memory (static RAM) device, wherein the static RAM device is coupled to the processor.

9. The hybrid storage device of claim 1, further comprising:
a configuration device, wherein the configuration device is coupled to the processor, whereby the configuration device is used to configure the persistent memory device.

10. The hybrid storage device of claim 1, further comprising:
a power distributor device that provides power to the apparatus.

11. The hybrid storage device of claim 10, wherein the power distributor device includes a battery charge, and wherein the apparatus is powered from the battery charge.

12. The hybrid storage device of claim 1, further comprising:
a backup power source coupled to the volatile memory device, wherein the backup power source provides power to the volatile memory device in the event of power loss in the apparatus, whereby the first set of information in the volatile memory device is preserved such that the time required to make the first information available to the host computer is reduced.

13. The hybrid storage device of claim 1, further comprising a status monitoring device, wherein the status monitoring device monitors one or more of the processor, the persistent memory device, the volatile memory device, the memory loader module, and the storage drive interface controller.

14. A system comprising:
a host computer; and
a hybrid storage device coupled to the host computer, wherein the hybrid storage device comprises:
a persistent memory device;
a volatile memory device;
a processor, wherein the persistent memory device and the volatile memory device are coupled to the processor;
a memory loader module that enables the processor to load a first set of information from the persistent memory device and to organize the first set of information according to a predetermined format in the volatile memory device; and
a storage drive interface controller that enables the processor to receive information access requests from the host computer, to respond to the information access requests using the first set of information in the volatile memory, and to provide a metadata descriptive of the first set of information to the host computer,
whereby the host computer is enabled to access the first set of information using the metadata without having the first set of information in a local memory of the host computer, and whereby the time required by the host computer to access the first set of information is reduced by having the first set of information in volatile memory.

15. A method comprising:
coupling a hybrid storage device to a host computer;
loading a first set of information from a persistent memory device to a volatile memory device and organizing the first set of information according to a predetermined format in the volatile memory device, wherein the persistent memory device and the volatile memory device are located in the hybrid storage device;
providing a metadata descriptive of the first set of information in the volatile memory device to a local random access memory (local RAM), wherein the local RAM is located in the host computer; and
accessing a second set of information using the metadata located in the local RAM, wherein the first set of information located in the volatile memory device includes the second set of information.

16. The method of claim 15, wherein the loading a first set of information includes:
accessing a compressed data image located in the persistent memory device; and
generating an uncompressed data image from the compressed data image, wherein the uncompressed data image is located in the volatile memory device.

17. The method of claim 16, wherein the first set of information includes a root filesystem.

18. The method of claim 15, wherein the accessing a second set of information comprises:
checking for the presence of a target data block in the local RAM, wherein the target data block includes the second set of information;
loading the target data block from the volatile memory device into the local RAM;
writing to the target block in the local RAM; and
updating the target block in the volatile memory device.

19. A method comprising:
coupling a hybrid storage device to a host computer;
loading a first set of information from a persistent memory device to a volatile memory device and organizing the first set of information according to a predetermined format, wherein the persistent memory device and the volatile memory device are located in the hybrid storage device;
loading access information to a local random access memory (local RAM), wherein the local RAM is located in the host computer, and wherein the access information includes information necessary to access the first set of information in the volatile memory; and
writing a second set of information from local RAM, using the access information located in the local RAM, to the volatile memory device.
